(19) United States
(12) Patent Application Publication
(10) Pub. No.: US 2009/0090981 A1
(43) Pub. Date: Apr. 9, 2009

(54) SEMICONDUCTOR DEVICE

(76) Inventor: Kazuhiro NATSUAKI, Nara-shi (JP)

Correspondence Address: BIRCH STEWART KOLASCH & BIRCH, PO BOX 747, FALLS CHURCH, VA, 22040-0747, US

(21) Appl. No.: 12/244,561

(22) Filed: Oct. 2, 2008

(30) Foreign Application Priority Data
Oct. 5, 2007 (JP) 2007-261488
Jul. 22, 2008 (JP) 2008-188454

(51) Int. Cl. H01L 47/00

(52) U.S. Cl. 257/408; 257/E47.001

(57) ABSTRACT

A semiconductor device which has a high dielectric strength and allows its on resistance to be made sufficiently small is provided. This semiconductor device comprises a first electroconducive-type semiconductor layer, and a gate electrode which is disposed on a given region of an insulation film formed on the main surface of the semiconductor layer. The semiconductor layer includes: a body region of the first electroconducive type which is formed near the main surface side; a drain region of the second electroconducive type which is formed near the main surface side; and a buried region of the second electroconducive type which is formed in a position that is not right under the body region and right under at least the drain region and is connected to the drain region.

### CROSS-REFERENCE TO RELATED APPLICATIONS

This application is based on Japanese Patent Application Nos. 2007-261488 filed on Oct. 5, 2007 and 2008-188454 filed on Jul. 22, 2008, the contents of which are hereby incorporated by reference.

### BACKGROUND OF THE INVENTION

1. Field of the Invention

The present invention relates to a semiconductor device, more particularly, to a semiconductor device which includes a MOS transistor.

2. Description of Related Art

Conventionally, a semiconductor device including an LDMOS (laterally diffused MOS) FET (hereinafter, referred to as an LDMOS) that is used at a comparatively low voltage of dozens of volts is known.

FIG. 6 is a sectional view showing a structure of a semiconductor device which includes a conventional LDMOS. As shown in FIG. 6, a semiconductor device 101 including a conventional LDMOS is an N channel-type MOS transistor and comprises a P-type semiconductor substrate 102, a gate oxide film 103 formed on the main surface of the P-type semiconductor substrate 102, and a gate electrode 104 formed on a given region of the gate oxide film 103. The P-type semiconductor substrate 102 is equipped with an N⁻-type well region 111 which is formed as a drift region to cover the lower surface of the gate electrode 104, and a P⁻-type body region 112 which is formed near the main surface side in the N⁻-type well region 111. The gate electrode 104 is disposed straddling the N⁻-type well region 111 and the P⁻-type body region 112. In a region which is present near the main surface side in the P⁻-type body region 112 and near one side (in an arrow A direction) of the gate electrode 104, the following regions are formed from the gate electrode 104 side in the following order of: an N⁺-type source region 113 (near the gate electrode 104) and a P⁺-type back gate region 114. This P⁺-type back gate region 114 is formed to control the back gate potential. In a region which is present near the main surface side in the N⁻-type well region 111 and near the other side (in an arrow B direction) of the gate electrode 104, an N⁺-type drain region 115 having a depth smaller than that of the P⁻-type body region 12 is formed.

The semiconductor device 101 having the LDMOS described above is required to have a high dielectric strength and a low on resistance.

The dielectric strength of the semiconductor device 101 is considerably influenced by concentrations of the N⁻-type well region 111 and the P-type body region 112 and by the distance L101 between the P⁻-type body region 112 and the N⁺-type drain region 115. Specifically, the lower the concentrations of the N⁻-type well region 111 and the P⁻-type body region 112 become, the higher the dielectric strength becomes. And the longer the distance L101 between the P⁻-type body region 112 and the N⁺-type drain region 115 becomes, the higher the dielectric strength becomes.

The on resistance of the semiconductor 101 is considerably influenced by resistance of a gate portion 120 (a region between the N⁺-type source region 113 and a drift region (the N⁻-type well region 111) below the gate electrode 104) and by resistance of a drift portion 121 (a region between the P⁻-type body region 112 and the N⁺-type drain region 115 below the gate electrode 104). Even if it is tried to shorten a gate length L102 to make the resistance of the gate portion 120 small, because the gate length L102 depends on machining accuracy of a production apparatus at the time of machining, it is hard to make the gate length L102 smaller than the machining accuracy. So, there is a limit to reduction of the resistance of the gate portion 120. To make the resistance of the drift portion 121 small, for example, it is possible to make a try to shorten the length L101 of the drift portion 121 or to raise the concentration of the N⁻-type well region 111. However, if the length L101 of the drift region 121 is shortened or the concentration of the N⁻-type well region 111 is raised, it is disadvantageous in that the dielectric strength is lowered.

For example, JP-A-2006-202810 has proposed a structure to drop the resistance of the drift portion 121 without shortening the length L101 of the drift portion 121 and without raising the concentration of the N⁻-type well region 111.

FIG. 7 is a sectional view showing a structure of a semiconductor device including the LDMOS disclosed in JP-A-2006-202810. FIG. 8 is a view showing an impurity concentration profile of a sectional region taken along the 200-200 line in FIG. 7. FIG. 9 is a sectional view showing an electric current (current) path in the semiconductor device including the LDMOS disclosed in JP-A-2006-202810 which is shown in FIG. 7. As shown in FIG. 7, the semiconductor device 201 including the LDMOS disclosed in JP-A-2006-202810 is an N channel-type MOS transistor and comprises a P-type semiconductor substrate 202, a gate oxide film 203 formed on the main surface of the P-type semiconductor substrate 202, and a gate electrode 204 formed on a given region of the gate oxide film 203. The P-type semiconductor substrate 202 is equipped with an N-type well region 211 which is formed as a drift region to cover the lower surface of the gate electrode 204, and a P⁻-type body region 212 which is formed near the main surface side in the N⁻-type well region 211. The gate electrode 204 is disposed straddling the N⁻-type well region 211 and the P⁻-type body region 212. In a region which is present near the main surface side in the P⁻-type body region 212 and near one side (in an arrow A direction) of the gate electrode 204, the following regions are formed from the gate electrode 204 side in the following order of: an N⁺-type source region 213 (near the gate electrode 204) and a P⁺-type back gate region 214. This P⁺-type back gate region 214 is formed to control the back gate potential. In a region which is present near the main surface side in the N⁻-type well region 211 and near the other side (in an arrow B direction) of the gate electrode 204, an N⁺-type drain region 215 is formed.

In the semiconductor device 201 including the LDMOS disclosed in JP-A-2006-202810, the N⁺-type drain region 215 is formed to substantially the same depth as that of the N⁻-type well region 211. According to this structure, because it is possible to make a current path between the P⁻-type body region 212 and the N⁺-type drain region 215 large compared with that in the conventional semiconductor device 101, resistance of the drift portion can be lowered. Consequently, in the semiconductor device 201 disclosed in JP-A-2006-202810, the on resistance can be lowered to some extent compared with that of the conventional semiconductor device 101.

However, in the semiconductor device 201 disclosed in JP-A-2006-202810, because impurities are introduced by ion implantation into the P-type semiconductor substrate 202 to form the N⁺-type drain region 215, impurity concentration of the surface side of the N⁺-type drain region 215 becomes high as shown in FIG. 8. A current path has been analyzed by simulation using a structure in which the N⁺-type drain region 215 is formed to substantially the same depth as that of the N⁻-type well region 211.

In the structure in which the N⁺-type drain region 215 is formed to substantially the same depth as that of the N⁻-type well region 21 1, as shown in FIG. 9, a current path 220 (a slanted-line portion) has proved to be so formed as to spread into an arc shape between the P-type body region 212 and the N⁺-type drain region 215. In other words, a region (a surface side portion) where the impurity concentration of the N⁺-type drain region 215 is high has proved to serve as a current path, while a region where the impurity concentration is low has proved not to serve as a current path. As described above, the semiconductor device 201 disclosed in JP-A-2006-202810 has a problem that it is hard to make the on resistance sufficiently small.

### SUMMARY OF THE INVENTION

The present invention has been made to cope with the conventional problems, and it is an object of the present invention to provide a semiconductor device that has a high dielectric strength and allows its on resistance to be made sufficiently small.

To achieve the object, a semiconductor device according to one aspect of the present invention comprises: a first electroconducive-type semiconductor layer; and a gate electrode which is disposed on a given region of an insulation film formed on the main surface of the semiconductor layer, the semiconductor layer includes: a second electroconducive-type drift region which is so formed as to cover a lower side of the gate electrode; a body region of the first electroconducive type which is formed near the main surface side in the drift region; a source region of the second electroconducive type which is formed near the main surface side in the body region and near one side of the gate electrode; a drain region of the second electroconducive type which is formed near the main surface side in the drift region and near the other side of the gate electrode; a buried region of the second electroconducive type which is formed in a position that is not right under the body region and right under at least the drain region and is connected to the drain region, the semiconductor layer includes: a semiconductor substrate of the first electroconducive type; and an epitaxial layer of the first electroconducive type which is formed on the semiconductor substrate, wherein the buried region is formed from an upper portion of the semiconductor substrate and to a lower portion of the epitaxial layer.

In the semiconductor device according to this one aspect, as described above, the buried region of the second electroconducive type which is formed in a position right under at least the drain region and is connected to the drain region is disposed in the semiconductor layer, thereby not only a region between the body region and the drain region but also a region between the body region and the buried region can be made serve as a current path. Accordingly, because the current path can be made sufficiently large, electric resistance (resistance) of the current path can be made sufficiently small. Consequently, it is possible to sufficiently lower the on resistance of the semiconductor device. Besides, the buried region is formed on a position that is not right under the body region, thereby it is possible to prevent the distance between the body region and the buried region from becoming short. Accordingly, the dielectric strength of the semiconductor device can be prevented from becoming low.

In the semiconductor device according to one aspect, as described above, the buried region is formed from an upper portion of the semiconductor substrate to a lower portion of the epitaxial layer, thereby the buried region having a high impurity concentration can be easily formed in a position (a deep position) sufficiently away from the main surface of the semiconductor layer (the epitaxial layer). Accordingly, because the current path can be made sufficiently large in the depth direction, the resistance of the current path can be easily made sufficiently small. Consequently, it is possible to sufficiently lower the on resistance of the semiconductor device.

In the semiconductor device according to one aspect, it is preferable that an end portion of the buried region near the body region side is formed closer to the body region side than an end potion of the drain region near the body region side. According to this structure, the buried region can be formed as close to the body region as possible, provided it is not located right under the body region. Accordingly, it is possible to more sufficiently lower the on resistance of the semiconductor device.

In the semiconductor device according to one aspect, it is preferable that an impurity concentration profile of the second electroconducive type in the depth direction of the drain region and the buried region has at least two impurity concentration peaks, that is, one in the drain region and the other in the buried region. According to this structure, the buried region having a high impurity concentration can be easily formed in a position (a deep position) sufficiently away from the main surface of the semiconductor layer (the epitaxial layer). Accordingly, because the current path can be made sufficiently large in the depth direction, the resistance of the current path can be made more sufficiently small.

In the semiconductor device according to one aspect, it is preferable that the distance from the body region to the buried region is substantially the same as that from the body region to the drain region. According to this structure, it is possible to prevent either one of the buried region and the drain region form being disposed closer to the body region than the other of the buried region and the drain region. Accordingly, it is possible to prevent the dielectric strength of the semiconductor device being lowered by either one of the buried region and the drain region.

In the semiconductor device according to one aspect, it is preferable that the drain region is formed to substantially the same depth as that of the body region or to a depth larger than the body region. According to this structure, because the drain region and the buried region can be easily formed in a position (a deep position) away from the main surface of the semiconductor layer, the current path formed between the drain region and the buried region can be easily made large.

In the semiconductor device according to one aspect, it is preferable that the first electroconductive type is the P type and the second electroconductive type is the N type. According to this structure, because the majority carrier in the drain region and the buried region are electrons, it is possible to easily lower the on resistance of the semiconductor device compared with that of the semiconductor device in which the majority carrier are holes (positive holes).

In the semiconductor device in which the first electroconductive type is the P type and the second electroconductive type is the N type, it is preferable that an N-type impurity which is used to form the drain region is phosphorus. According to this structure, because phosphorus has a diffusion speed higher than, for example, antimony and arsenic, the drain region can be formed to a desired depth with less heat treatment compared with that in the case where antimony or arsenic is used to form the drain region. Accordingly, productivity in producing the semiconductor device can be improved.

In the semiconductor device in which the first electroconductive type is the P type and the second electroconductive type is the N type, it is preferable that an N-type impurity which is used to form the buried region is antimony or arsenic. According to this structure, because antimony or arsenic have a diffusion speed lower than, for example, phosphorus, it is possible to prevent the impurity from being diffused excessively by heat treatment after the formation of the buried region so that the buried region does not become too large compared with that in the semiconductor device in which phosphorus is used to form the buried region. Accordingly, the buried region can be easily formed to a desired size.

In the semiconductor device according to one aspect, it is preferable that the epitaxial layer has a thickness smaller than the sum of a diffusion distance of impurity which is diffused from the main surface of the epitaxial layer in a depth direction to form the drain region, and a diffusion distance of impurity which is diffused toward the drain region side to form the buried region. According to this structure, because the drain region and the buried region can be easily connected to each other, not only the region between the body region and the drain region but also the region between the body region and the buried region can be easily made serve as a current path.

In the semiconductor device according to one aspect, it is preferable that a connection portion between the drain region and the buried region has an impurity concentration which is 1×10¹⁸ atoms/cm³ or more and equal to or less than the maximum value of impurity concentrations of the drain region and the maximum value of impurity concentrations of the buried region. In such a structure that the connection portion between the drain region and the buried region has an impurity concentration of 1×10¹⁸ atoms/cm³ or more, because resistance of the connection portion between the drain region and the buried region can be sufficiently small, the carriers can move smoothly between the drain region and the buried region. Accordingly, not only the region between the body region and the drain region but also the region between the body region and the buried region can be easily made serve as a current path. Consequently, the on resistance of the semiconductor device can be made sufficiently small. Besides, the connection portion between the drain region and the buried region is so structured as to have an impurity concentration which is equal to or less than the maximum value of impurity concentrations of the drain region and the maximum value of impurity concentrations of the buried region, thereby the impurity concentration profile of the second electroconductive type in the depth direction of the drain region and the buried region has at least two impurity concentration peaks, that is, one in the drain region and the other in the buried region. According to this structure, the buried region having a high impurity concentration can be easily formed in a position (a deep position) sufficiently away from the main surface of the semiconductor layer (the epitaxial layer). Consequently, because the current path can be made sufficiently large in the depth direction, the resistance of the current path can be made more sufficiently small.

In the semiconductor device in which the connection portion between the drain region and the buried region has an impurity concentration which is 1×10¹⁸ atoms/cm³ or more, it is preferable that the maximum value of impurity concentrations of the buried region is in a range of 1×10¹⁹ atoms/cm³ to 1×10²⁰ atoms/cm³. When the maximum value of impurity concentrations of the buried region is 1×10¹⁹ atoms/cm³ or more, the connection portion between the drain region and the buried region can be easily so structured as to have an impurity concentration of 1×10¹⁸ atoms/cm³ or more. Besides, when the maximum value of impurity concentrations of the buried region is 1×10²⁰ atoms/cm³ or less, it is possible to prevent the impurity in the buried region from being diffused excessively by heat treatment so that the buried region does not become too large. Accordingly, the buried region can be easily formed to a desired size.

In the semiconductor device according to one aspect, it is preferable that the semiconductor substrate and the epitaxial layer have substantially the same impurity concentration. According to this structure, a depletion layer which is formed around the body region when a voltage is applied to the body region can be prevented from being so formed as to have thicknesses (widths) different from each other in the semiconductor substrate and the epitaxial layer. Accordingly, the dielectric strength between the buried region and the body region and the dielectric strength between the drain region and the body region can be easily so made as to have the same largeness.

In the semiconductor device according to one aspect, it is preferable that the epitaxial layer has a thickness which is 3 μm or more and 7 μm or less. When the epitaxial layer is so structured as to have a thickness of 3 μm or more, because the buried region can be prevented from being formed near the body region, it is possible to curb decrease of the dielectric strength of the semiconductor device. When the epitaxial layer is so structured as to have a thickness of 7 μm or less, because it is not necessary to form the drain region so deeply as to connect the drain region to the buried region, the impurity concentration of the connection portion between the drain region and the buried region can be prevented from becoming too low. Accordingly, the resistance between the buried region and the drain region can be prevented from becoming large.

In the semiconductor device according to one aspect, a collector compensation region and a collector buried region are further provided to form a bipolar transistor. The drain region is formed at the same time as the collector compensation region of the bipolar transistor, and the buried region is formed at the same time as the collector buried region of the bipolar transistor. In this case, productivity in producing the drain and buried regions can be increased compared with that in the case where the drain region and the buried region are produced in the processes different from those for the collector compensation region and the collector buried region of the bipolar transistor.

### DESCRIPTION OF THE DRAWINGS

FIG. 1 is a sectional view showing a structure of a semiconductor device including an LDMOS according to an embodiment of the present invention.

FIG. 2 is a sectional view showing a depletion layer which is formed in an N⁻-type well region of a semiconductor device including the LDMOS according the embodiment illustrated in FIG. 1.

FIG. 3 is a view showing an impurity concentration profile of a sectional region taken along the 100-100 line in FIG. 1.

FIG. 4 is a sectional view showing a current path in a semiconductor device including the LDMOS according the embodiment illustrated in FIG. 1.

FIG. 5 is a view showing an impurity concentration profile of a modified semiconductor device according to the present invention.

FIG. 6 is a sectional view showing a structure of a semiconductor device including a conventional LDMOS.

FIG. 7 is a sectional view showing a structure of a semiconductor device including the LDMOS illustrated in JP-A-2006-202810.

FIG. 8 is a view showing an impurity concentration profile of a sectional region taken along the 200-200 line in FIG. 7.

FIG. 9 is a sectional view showing a current path in a semiconductor device including the LDMOS illustrated in JP-A-2006-202810 illustrated in FIG. 7.

### DESCRIPTION OF PREFERRED EMBODIMENTS

Hereinafter, embodiments of the present invention are explained referring to the drawings.

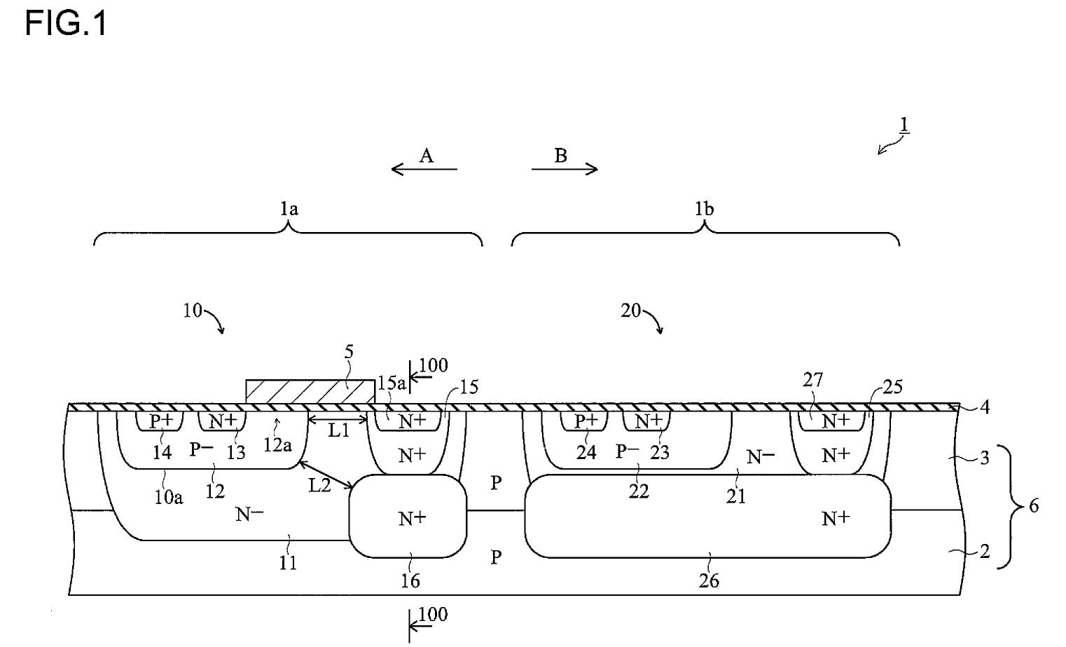

First, referring to FIGS. 1-4, a structure of a semiconductor 1 including an LDMOS according to an embodiment of the present invention is explained.

As shown in FIG. 1, the semiconductor device 1 according to an embodiment of the present invention comprises a P-type semiconductor substrate 2, a P-type epitaxial layer 3 formed on the main surface of the P-type semiconductor substrate 2, a gate oxide film 4 formed on the main surface of the P-type epitaxial layer 3, and a gate electrode 5 formed on a given region of the gate oxide film 4. A semiconductor layer 6 is comprised of the P-type semiconductor substrate 2 and the P-type epitaxial layer 3. The P-type semiconductor substrate 2 is an example of a “semiconductor substrate” according to the present invention, and the P-type epitaxial layer 3 is an example of an “epitaxial layer” according to the present invention. The gate oxide film 4 is an example of an “insulation film” according to the present invention. The P type (P⁺type, P⁻-type) is an example of a “first electroconductive type” according to the present invention.

Here, in the present embodiment, the semiconductor device 1 includes an LDMOS formed region 1a where an LDMOS 10, that is, an N channel-type MOS transistor is formed, and a bipolar transistor formed region 1b where a bipolar transistor 20 is formed.

The P-type semiconductor substrate 2 has a crystal axis of <100> and a resistivity of about 20 Ωcm. The P-type epitaxial layer 3 has a resistivity of about 20 Ωcm. The P-type epitaxial layer 3 is formed to a thickness of about 5 μm to about 7 μm. Specifically, the P-type epitaxial layer 3 is formed to a thickness smaller than the sum of a diffusion distance of the impurity which is diffused from the main surface of the P-type epitaxial layer 3 (the semiconductor layer 6) in a downward direction (a depth direction) to form an N⁺-type drain region 15 described later, and a diffusion distance of the impurity which is diffused in an upward direction (toward the N⁺-type drain region 15 side) to form an N⁺-type buried region 16. The P-type semiconductor substrate 2 and the P-type epitaxial layer 3 have substantially the same-largeness impurity concentration.

The gate oxide film 4 is formed of a silicon oxide film having a thickness of about 30 nm. The gate electrode 5 is formed of polysilicon and disposed only in the LDMOS formed region 1a in such a manner that the gate electrode 5 straddles an N⁻-type well region 11 and a P⁻-type body region 12 which are describe later.

In the LDMOS formed region 1a, in the semiconductor layer 6, a drift region, that is, the N⁻-type well region 11 is formed from the surface of the P-type epitaxial layer 3 to a halfway depth of the P-type semiconductor substrate 2 in such a manner that the N⁻-type well region 11 covers an region below the gate electrode 5. In this N⁻-type well region 11, phosphorus (P) is introduced as the N-type impurity. The N⁻-type well region 11 is an example of a “drift region” according to the present invention. The N type (N⁻type, N⁺type) is an example of a “second electroconductive type.”

In the N⁻-type well region 11, a P⁻-type body region 12 which is formed near the main surface side and has a depth of about 1.5 μm to about 2.0 μm is disposed. In this P⁻-type body region 12, boron (B) is introduced as the P-type impurity. The P⁻-type body region 12 is an example of a “body region” according to the present invention.

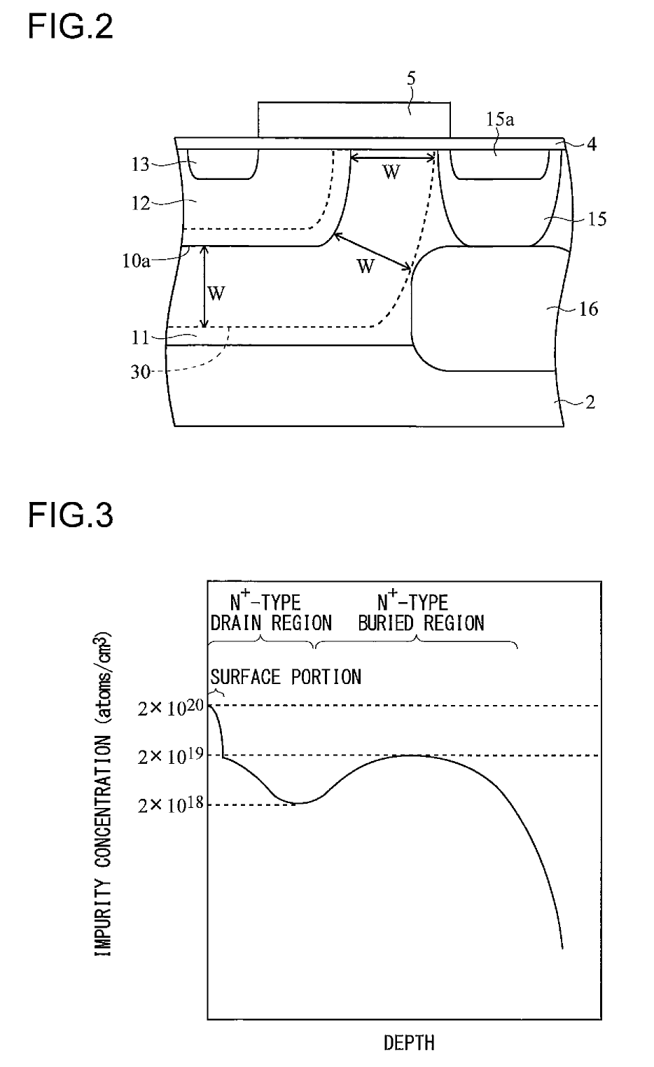

In the boundary region between the N-type well region 11 and the P⁻-type body region 12, as shown in FIG. 2, a depletion layer 30 is formed. This depletion layer 30 is formed in such a manner that when a voltage is applied to an N⁺-type drain region 15 described later, the depletion layer 30 extends from a boundary surface 10a between the N⁻-type well region 11 and the P⁻-type body region 12 by substantially a constant distance W.

As shown in FIG. 1, in a region near the main surface side in the P⁻-type body region 12 side and near one side (the arrow A direction) of the gate electrode 5, the following regions are formed from the gate electrode 5 side in the following order of: an N⁺-type source region 13 and a P⁺-type back gate region 14. The P⁻-type body region 12 short-circuits with the N⁺-type source region 13 via the P⁺-type back gate region 14 and a wiring, not shown. Thus, it is possible to prevent a parasitic NPN transistor from operating. The N⁺-type source region 13 is an example of a “source region” according to the present invention.

Besides, a surface portion 12a of the P-type body region 12 that is present below the gate electrode 15 and between the N⁺-type source region 13 and the N⁻-type well region 11 serves as a channel.

The N⁺-type source region 13 has a depth of about 0.2 μm. In the N⁺-type source region 13, phosphorus (P) is introduced as the N-type impurity, and has an impurity concentration of about 1×10²⁰ atoms/cm³.

In a region near the main surface side in the N⁻-type well region 11 and near the other side (the arrow B direction) of the gate electrode 5, an N⁺-type drain region 15 is formed. The N⁺-type drain region 15 is an example of a “drain region” according to the present invention.

In the present embodiment, in the N⁺-type drain region 15, phosphorus (P) is introduced as the N-type impurity. As shown in FIG. 3, the N⁺-type drain region 15 has an impurity concentration of about 2×10¹⁹ atoms/cm³ except a surface portion 15a. The surface portion 15a has a high impurity concentration of about 2×10²⁰ atoms/cm³ as the peak value (the maximum value).

Besides, in the present embodiment, as shown in FIG. 1, the N⁺-type drain region 15 is formed to substantially the same depth as that of the P⁻-type body region 12 or to a depth slightly deeper than that of the N⁻-type well region 11.

In the present embodiment, in a position which is not right under the P⁻-type body region 12 (a position near the other side (the arrow B direction) of the P⁻-type body region 12) and is right under the N⁺-type drain region 15, an N⁺-type buried region 16 is so formed as to be connected to the N⁺-type drain region 15. This N⁺-type buried region 16 is disposed from the upper portion of the P-type semiconductor substrate 2 to the lower portion of the P-type epitaxial layer 3. The N⁺-type buried region 16 is an example of a “buried region” according to the present invention.

In the present embodiment, in the N⁺-type buried region 16, antimony (Sb) is introduced as the N-type impurity. As shown in FIG. 3, the maximum (peak) value of impurity concentrations of the N⁺-type buried region 16 is about 2×10¹⁹ atoms/cm³.

As described above, the N⁺-type buried region 16 has substantially the same impurity concentration as that of the N⁺-type drain region 15 except the surface portion 15a. Here, the dielectric strengths of the N⁺-type drain region 15 and the N⁺-type buried region 16 are determined depending on the impurity concentrations of the N⁺-type drain region 15 and the N⁺-type buried region 16 and on the impurity concentrations of the P-type semiconductor substrate 2 and the P-type epitaxial layer 3. Accordingly, as described above, the impurity concentration of the P-type semiconductor substrate 2 is made substantially equal to the impurity concentration of the P-type epitaxial layer 3, and the impurity concentration of the N⁺-type drain region 15 is made substantially equal to the impurity concentration of the N⁺-type buried region 16, thereby the dielectric strengths of the N⁺-type drain region 15 and the N⁺-type buried region 16 can be prevented from being limited by one of the N⁺-type drain region 15 and the N⁺-type buried region 16 or by one of the P-type semiconductor substrate 2 and the P-type epitaxial layer 3. The dielectric strengths of the N⁺-type drain region 15 and the N⁺-type buried region 16 are usually set larger than the dielectric strength between the N⁺-type drain region 15 and the P⁻-type body region 12 and than the dielectric strength between the N⁺-type buried region 16 and the P⁻-type body region 12. However, in the present embodiment, to reduce the on resistance of the semiconductor 1 (the LDMOS 10), because the impurity concentrations of the N⁺-type drain region 15 and the N⁺-type buried region 16 are set high, the dielectric strengths of the N⁺-type drain region 15 and the N⁺-type buried region 16 tend to become small. Accordingly, the structure described above is effective.

In the present embodiment, the connection portion between the N⁺-type drain region 15 and the N⁺-type buried region 16 has an impurity concentration of about 2×10¹⁸ atoms/cm³.

In the present embodiment, the N-type impurity concentration profile in the depth direction of the N⁺-type drain region 15 and the N⁺-type buried region 16 has two impurity concentration peaks, that is, the impurity concentration peak in the N⁺-type drain region 15 and the impurity concentration peak in the N⁺-type buried region 16.

As shown in FIG. 1, in the present embodiment, the N⁺-type buried region 16 is also formed in another position besides the position right under the N⁺-type drain region 15. Specifically, the end portion of the N⁺-type buried region 16 near the P⁻-type body region 12 side (the arrow A direction side) is disposed closer to the P⁻-type body region 12 side (the arrow A direction side) than the position right under the end portion of the N⁺-type drain region 15 near the P⁻-type body region 12 (the arrow A direction side). In other words, the N⁺-type buried region 16 is formed closer to the P⁻-type body region 12 side than the N⁺-type drain region 15 when seen in a plane. Besides, the distance L1 between the N⁺-type drain region 15 and the P⁻-type body region 12 and the distance L2 between the N⁺-type buried region 16 and the P⁻-type body region 12 are so formed as to be substantially equal to each other.

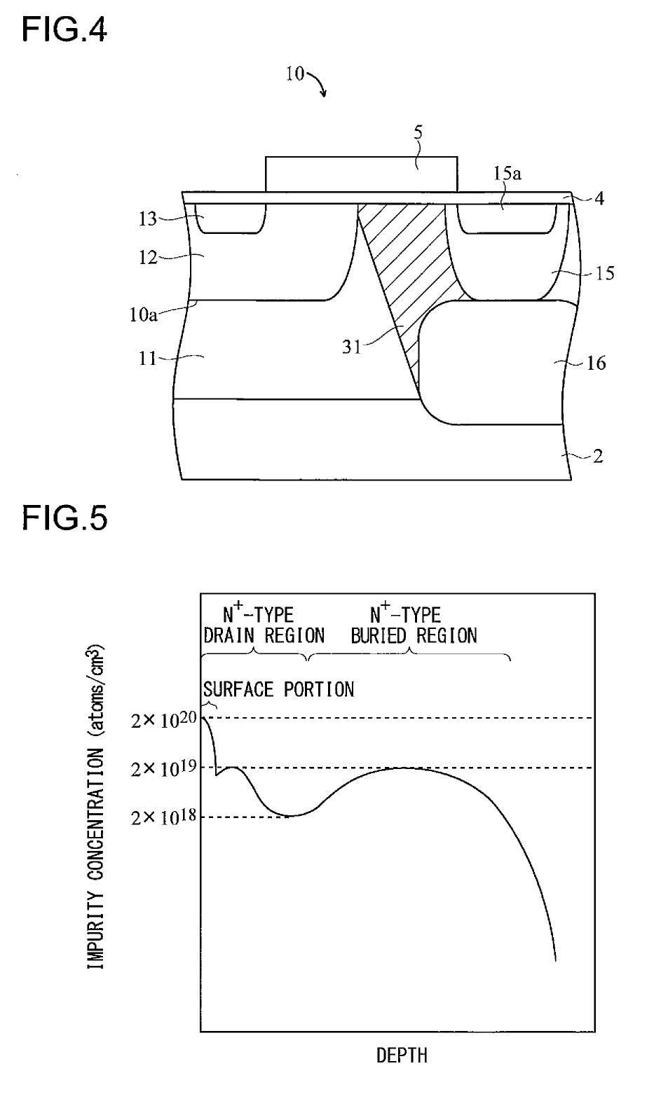

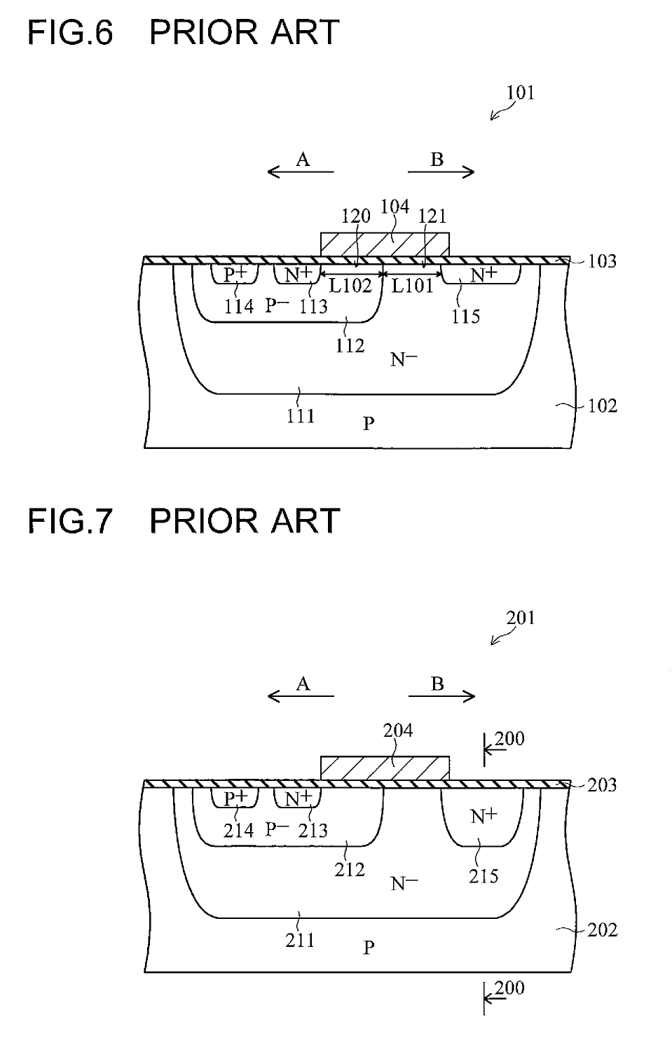

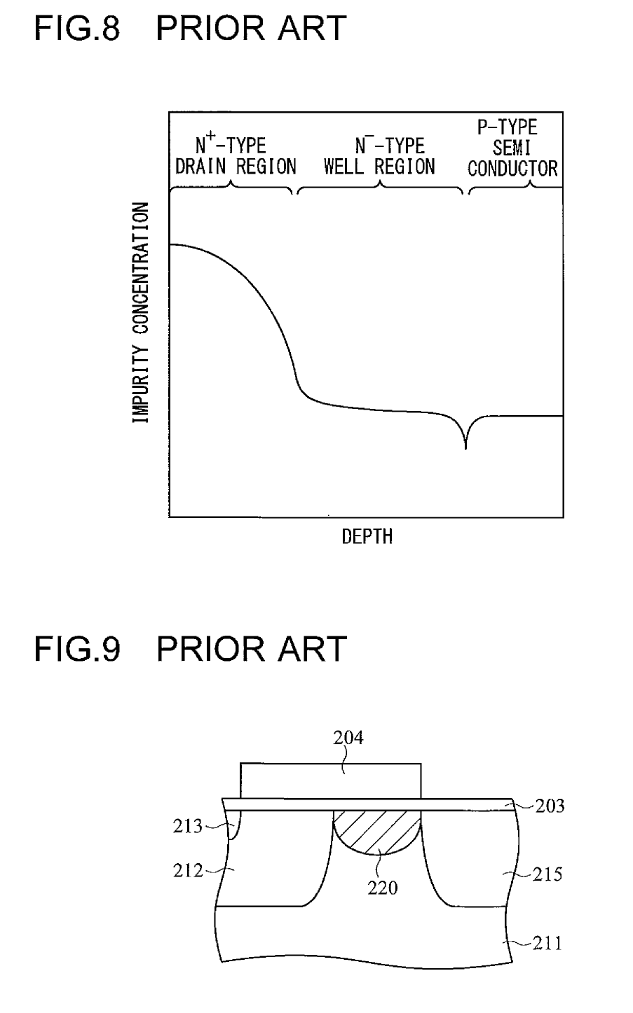

In the structure of the LODMOS 10 according to the present embodiment described above, according to a result of analysis of the current path carried out by simulation, as shown in FIG. 4, the current path 31 (the slanted-line portion) is so formed as to extend from the upper portion of the N⁺-type drain region 15 to the lower portion of the N⁺-type buried region 16. This is because of the following reason, that is, the connection portion between the N⁺-type drain region 15 and the N⁺-type buried region 16 is so formed as to have an impurity concentration of about 2×10¹⁸ atoms/cm³ or more, thereby it is possible to make the resistance of the connection portion between the N⁺-type drain region 15 and the N⁺-type buried region 16 sufficiently small, and it is also possible to make the region between the N⁺-type buried region 16 and the P⁻-type body region 12 function as the current path 31.

On the other hand, in the bipolar transistor formed region 1b, as shown in FIG. 1, the gate electrode 5 is not formed on the gate oxide film 4.

Besides, in the bipolar transistor formed region 1b, the following regions are disposed in the semiconductor layer 6, that is, an N⁻-type well region 21, a P⁻-type body region 22, an N⁺-type emitter region 23, a P⁺-type base region 24, and an N⁺-type collector compensation region 25 (an N⁺-type collector region 27), which are formed into the same structures respectively as those of and at the same time of the formation of, in the LDMOS formed region 1a, the N⁻-type well region 11, the P⁻-type body region 12, the N⁺-type source region 13, P⁺-type back gate region 14, and the N⁺-type drain region 15 (the surface portion 15a). The N⁺-type collector compensation region 25 is an example of a “collector compensation region” according to the present invention.

An N⁺-type buried region 26 is formed from the position right under the P⁻-type body region 22 to the position right under the N⁺-type collector compensation region 25 so that the N⁺-type collector buried region 26 is connected to the N⁺-type collector compensation region 25. The other structures of this N⁺-type collector buried region 26 are the same as those of the N⁺-type buried region 16, and the N⁺-type collector buried region 26 is formed at the same time when the N⁺-type buried region 16 is formed. The N⁺-type collector compensation region 25 and the N⁺-type collector buried region 26 are disposed in the bipolar transistor 20, thereby because the collector resistance can be made small, the saturation voltage can be decreased and the bipolar transistor 20 can be formed as a high-speed device. The N⁺-type collector buried region 26 is an example of a “collector buried region” according to the present invention.

Next, referring to FIG. 1, production processes of the semiconductor device 1 according to the embodiment of the present invention are explained.

First, as shown in FIG. 1, antimony (Sb) as the N-type impurity is introduced by ion implantation or by coating diffusion into a given region of the main surface of the P-type semiconductor substrate 2 which has the crystal axis of <100> and a resistivity of about 20 Ωcm. And heat treatment is carried out at a temperature of about 1200° C. and for about 60 minutes to drive in antimony (Sb) as the N-type impurity, thereby the N⁺-type buried region 16 and the N⁺-type collector buried region 26 are formed.

Then, after the oxide film on the surface of the P-type semiconductor substrate 2 is removed, the P-type epitaxial layer 3 having a resistivity of about 20 Ωcm is formed to a thickness of about 5 μm to about 7 μm on the main surface of the P-type semiconductor substrate 2. And the P-type impurity is implanted (ion-implanted) by ion implantation at a rate of about 4×10¹² atoms/cm² so that the impurity concentrations of the P-type semiconductor substrate 2 and the P-type epitaxial layer 3 have substantially the same largeness.

Then, after phosphorus (P) as the N-type impurity is ion-implanted at a rate of about 1×10¹³ atoms/cm² from the main surface of the P-type epitaxial layer 3, heat treatment (drive in) is carried out for about 400 minutes at a temperature of about 1200° C., thereby the N⁻-type well regions 11, 21 are formed from the surface of the P-type epitaxial layer 3 to a halfway depth of the P-type semiconductor substrate 2. At this time, the N⁺-type buried region 16 and the N⁺-type collector buried region 26 are formed by thermal diffusion from the upper portion of the P-type semiconductor substrate 2 to the lower potion of the P-type epitaxial layer 3. Besides, at this time, the maximum values of impurity concentrations of the N⁺-type buried region 16 and the N⁺-type collector buried region 26 become about 2×10¹⁹ atoms/cm³

Boron (B) as the P-type impurity is ion-planted into given regions of the N⁻-type well regions 11, 21 at a rate of about 1×10¹³ atoms/cm², thereby the P⁻-type body regions 12, 22 having a depth of about 1.5 μm to about 2.0 μm are formed.

At this time, in the present embodiment, the P⁻-type body regions 12 is formed in a position (a position away from the N⁺-type buried region 16 in the arrow A direction) which is not right above the N⁺-type buried region 16.

Next, the gate oxide film 4 formed of a silicon oxide film which has a thickness of about 30 nm is formed on the main surface of the P-type epitaxial layer 3 (the semiconductor layer 6). And polysilicon is formed on the gate oxide film 4 and patterning is applied to the polysilicon, thereby the gate electrode 5 is formed. At this time, the gate electrode 5 is so formed as to straddle the N⁻-type well region 11 and the P⁻-type body regions 12. During the time of operation of the LDMOS 10, the surface portion 12a of the P⁻-type body region 12 that is present below the gate electrode 5 and between the N⁺-type source region 13 and the N⁻-type well region 11 serves as a channel.

Then, for self-matching with the gate electrode 5, phosphorus (P) as the N-type impurity is ion-implanted at a rate of about 6×10¹⁵ atoms/cm² into the N⁻-type well region 11 that is opposite to the P⁻-type body regions 12 (the arrow B direction) with respect to the gate electrode 5. A the same time, phosphorus (P) as the N-type impurity is also ion-implanted into a region of the N⁻-type well region 21 in the arrow B direction at a rate of about 6×10¹⁵ atoms/cm². And annealing is carried out for about 60 minutes at a temperature of about 1000° C. to form the N⁺-type drain region 15 and the N⁺-type collector compensation region 25.

At this time, in the present embodiment, the N⁺-type drain region 15 and the N⁺-type collector compensation region 25 are formed to substantially the same depths (about 1.5 μm to about 2.0 μm) as those of the P⁻-type body regions 12, 22 or to depths slightly deeper than those of the P⁻-type body regions 12, 22. The impurity in the N⁺-type drain region 15 is diffused in a downward direction (a depth direction) and the impurity in the N⁺-type buried region 16 is diffused in an upward direction (toward the N⁺-type drain region 15 side), thereby the N⁺-type drain region 15 and the N⁺-type buried region 16 are connected to each other. Besides, the connection portion between the N⁺-type drain region 15 and the N⁺-type buried region 16 and the connection portion between the N⁺-type collector compensation region 25 and the N⁺-type collector buried region 26 have an impurity concentration of about 2×10¹⁸ atoms/cm³.

In addition, at this time, the N⁺-type buried region 16 is also formed in another position besides the position which is not right under the N⁺-type drain region 15. Specifically, the N⁺-type buried region 16 is formed in such a manner that the end portion of the N⁺-type buried region 16 near the P⁻-type body region 12 side (the arrow A direction side) is closer to the P⁻-type body region 12 side (the arrow A direction side) than the position right under the end portion of the N⁺-type drain region 15 near the P⁻-type body region 12 side (the arrow A direction side).

And, for self-matching with the gate electrode 5, phosphorus (P) as the N-type impurity is ion-implanted at a rate of about 4×10¹⁵ atoms/cm² into the P⁻-type body regions 12 and into the N⁺-type drain region 15. At the same time, phosphorus (P) as the N-type impurity is also ion-implanted into the P-type body region 22 and into the N⁺-type collector compensation region 25 at a rate of about 4×10¹⁵ atoms/cm². In this way, the N⁺-type source region 13 having a depth of about 0.2 μm is formed in the region which is present near the main surface side in the P⁻-type body regions 12 and near one side (the arrow A direction) of the gate electrode 5, and the surface 15a of the N⁺-type drain region 15 has an impurity concentration of about 2×10²⁰ atoms/cm³ as the peak value (the maximum value). Besides, an N⁺-type emitter region 23 having a depth of about 0.2 μm is formed near the main surface side in the P-type body region 22, and an N⁺-type collector region 27 which has an impurity concentration of about 2×10²⁰ atoms/cm³ as the peak value (the maximum value) is formed in the surface portion of the N⁺-type collector compensation region 25.

As described above, ion implantation is carried out into the N⁺-type drain region 15 and into the N⁺-type collector compensation region 25 to raise the impurity concentrations of the surface portions of the N⁺-type drain region 15 and the N⁺-type collector compensation region 25, thereby it is possible to prevent the contact resistances of the N⁺-type drain region 15 and the N⁺-type collector compensation region 25 from becoming high. Specifically, when forming the N⁺-type drain region 15 and the N⁺-type collector compensation region 25, ion implantation is carried out into a deep position of the semiconductor layer 6 to connect the N⁺-type drain region 15 and the N⁺-type collector compensation region 25 with the N⁺-type buried region 16 and the N⁺-type collector buried region 26, respectively, which can cause the impurity concentrations of the surface portions of the N⁺-type drain region 15 and the N⁺-type collector compensation region 25 to become low. Also in such a case, it is possible to raise the impurity concentrations of the surface portions of the N⁺-type drain region 15 and the N⁺-type collector compensation region 25 by carrying out ion implantation into the N⁺-type drain region 15 and the N⁺-type collector compensation region 25. In this way, it is possible to prevent the contact resistances of the N⁺-type drain region 15 and the N⁺-type collector compensation region 25 from becoming high.

Then, the P⁺-type back gate region 14 and the P⁺-type base region 24 are formed in the positions near one side (the arrow A direction) of the P⁻-type body regions 12 and 22, respectively.

As described above, the semiconductor device 1 is produced.

As described above, in the present embodiments, in the semiconductor layer 6, the N⁺-type buried region 16 which is formed at least in the position right under the N⁺-type drain region 15 and is connected to the N⁺-type drain region 15 is disposed, thereby not only the region between the P⁻-type body region 12 and the N⁺-type drain region 15 but also the region between the P⁻-type body region 12 and the N⁺-type buried region 16 can be easily made serve as the current path 31. Thus, because the current path 31 can be formed sufficiently large, the resistance of the current path 31 can be made sufficiently small. Consequently, the on resistance of the semiconductor device 1 can be made sufficiently small. Besides, the P⁻-type buried region 16 is formed in the position which is not right under the P⁻-type body region 12, thereby it is possible to prevent the distance L2 between the P⁻-type body region 12 and the N⁺-type buried region 16 from becoming short. Accordingly, the dielectric strength of the semiconductor device 1 can be prevented from becoming low.

In the present embodiments, the N⁺-type buried region 16 is formed from the upper portion of the P-type semiconductor substrate 2 to the lower portion of the P-type epitaxial layer 3, thereby the N⁺-type buried region 16 having a high impurity concentration can be easily formed in the position (the deep position) away from the main surface of the semiconductor layer 6 (the P-type epitaxial layer 3). In this way, the current path 31 can be easily formed large in the depth direction. Consequently, because the resistance of the current path 31 can be easily made sufficiently small, the on resistance of the semiconductor device 1 can be easily made sufficiently small.

In the present embodiments, the end portion of the N⁺-type buried region 16 near the P⁻-type body region 12 side (the arrow A direction side) is disposed closer to the P⁻-type body region 12 side (the arrow A direction side) than the position right under the end portion of the N⁺-type drain region 15 near the P⁻-type body region 12 side (the arrow A direction side), thereby the N⁺-type buried region 16 can be formed as close to the P⁻-type body region 12 as possible, provided it is not located right under the P⁻-type body region 12. Accordingly, it is possible to more sufficiently lower the on resistance of the semiconductor device 1.

In the present embodiments, the N-type impurity concentration profile in the depth direction of the N⁺-type drain region 15 and the N⁺-type buried region 16 has two impurity concentration peaks, that is, the impurity concentration peak in the surface portion 15a of the N⁺-type drain region 15 and the impurity concentration peak in the N⁺-type buried region 16. In this way, the N⁺-type buried region 16 having a high impurity concentration can be formed in the position (the deep position) sufficiently away from the main surface of the semiconductor layer 6 (the P-type epitaxial layer 3). Accordingly, because the current path 31 can be easily formed large in the depth direction, the resistance of the current path 31 can be easily made more sufficiently small.

In the present embodiments, the distance L2 from the P⁻-type body region 12 to the N⁺-type buried region 16 is made to be substantially equal to the distance L1 from the P⁻-type body region 12 to the N⁺-type drain region 15. Therefore, it is possible to prevent either one of the N⁺-type buried region 16 and the N⁺-type drain region 15 from being disposed closer to the P⁻-type body region 12 than the other of the N⁺-type buried region 16 and the N⁺-type drain region 15. Accordingly, it is possible to prevent the dielectric strength of the semiconductor device 1 from being lowered (limited) by either one of the N⁺-type buried region 16 and the N⁺-type drain region 15.

Besides, in the present embodiments, the N⁺-type drain region 15 is formed to substantially the same depth as that of the P⁻-type body region 12 or to a depth deeper than the P⁻-type body region 12, thereby the N⁺-type drain region 15 and the N⁺-type buried region 16 can be easily formed in the position (the deep position) away from the main surface of the semiconductor layer 6 (the epitaxial layer 3). In this way, the current path 31 formed between the N⁺-type drain region 15 and the P⁻-type body region 12, and current path 31 formed between the N⁺-type buried region 16 and the P⁻-type body region 12 can be easily made large.

In the present embodiments, it is structured in such a manner that the majority carrier in the N⁺-type drain region 15 and the N⁺-type buried region 16 are electrons, thereby it is possible to easily lower the on resistance of the semiconductor device 1 compared with that in the case where the majority carrier are holes (positive holes).

In the present embodiments, phosphorus (P) is used as the impurity to form the N⁺-type drain region 15. Because phosphorus (P) has a diffusion speed higher than, for example, antimony (Sb) and arsenic (As), the N⁺-type drain region 15 can be formed to a desired depth with less heat treatment compared with that in the case where antimony (Sb) or arsenic (As) is used to form the N⁺-type drain region 15. Accordingly, productivity in producing the semiconductor device 1 can be improved.

In the present embodiments, antimony (Sb) is used as the impurity to form the N⁺-type buried region 16. Because antimony (Sb) has a diffusion speed lower than, for example, phosphorus (P), it is possible to prevent the impurity from being diffused excessively by heat treatment after the formation of the N⁺-type buried region 16 so that the N⁺-type buried region 16 does not become too large compared with that in the case where phosphorus (P) is used to form the N⁺-type buried region 16. Accordingly, the N⁺-type buried region 16 can be easily formed to a desired size. Consequently, because the N⁺-type buried region 16 can be prevented from being so formed as to extend to a point near the P⁻-type body region 12, it is possible to prevent the dielectric strength of the semiconductor device 1 from becoming low.

In the present embodiments, the P-type epitaxial layer 3 has a thickness smaller than the sum of the diffusion distance of the impurity which is diffused from the main surface of the P-type epitaxial layer 3 in the downward direction (the depth direction) to form the N⁺-type drain region 15, and the diffusion distance of the impurity which is diffused in the upward direction (toward the N⁺-type drain region 15 side) to form the N⁺-type buried region 16. In this case, because the impurity in the N⁺-type drain region 15 is diffused in the downward direction (the depth direction), and because the impurity in the N⁺-type drain region 16 is diffused in the upward direction (toward the N⁺-type drain region 15 side), thereby it is possible to easily connect the N⁺-type drain region 15 and the N⁺-type buried region 16 to each other. Consequently, not only the region between the P⁻-type body region 12 and the N⁺-type drain region 15 but also the region between the P⁻-type body region 12 and the N⁺-type buried region 16 can be easily made serve as the current path 31.

In the present embodiments, the connection portion between the N⁺-type drain region 15 and the N⁺-type buried region 16 is so structured as to have an impurity concentration of about 2×10¹⁸ atoms/cm³ (more than 1×10¹⁸ atoms/cm³). In this case, because the resistance of the connection portion between the N⁺-type drain region 15 and the N⁺-type buried region 16 can be sufficiently small, the carriers can move smoothly between the N⁺-type drain region 15 and the N⁺-type buried region 16. Accordingly, not only the region between the P⁻-type body region 12 and the N⁺-type drain region 15 but also the region between the P⁻-type body region 12 and the N⁺-type buried region 16 can be easily made serve as the current path 31. Consequently, the on resistance of the semiconductor device 1 can be made sufficiently small.

In the present embodiments, the connection portion between the N⁺-type drain region 15 and the N⁺-type buried region 16 is so structured as to have an impurity concentration which is equal to or less than the maximum impurity concentration (about 2×10²⁰ atoms/cm³) of the N⁺-type drain region 15 and the maximum impurity concentration (about 2×10¹⁹ atoms/cm³) of the N⁺-type buried region 16. In this way, it can be easily structured in such a manner that the N-type impurity concentration profile in the depth direction of the N⁺-type drain region 15 and the N⁺-type buried region 16 has two impurity concentration peaks, that is, one impurity concentration peak in the N⁺-type drain region 15 and the other impurity concentration peak in the N⁺-type buried region 16.

In the present embodiments, the maximum value of impurity concentrations of the N⁺-type buried region 16 is about 2×10¹⁹ atoms/cm³ (more than 1×10¹⁹ atoms/cm³), thereby the resistance of the connection portion between the N⁺-type drain region 15 and the N⁺-type buried region 16 can be easily made sufficiently small.

In the present embodiments, the maximum value of impurity concentrations of the N⁺-type buried region 16 is about 2×10¹⁹ atoms/cm³ (less than 1×10²⁰ atoms/cm³), thereby it is possible to prevent the impurity in the N⁺-type buried region 16 from being diffused excessively by heat treatment so that the N⁺-type buried region 16 does not become too large. Accordingly, the N⁺-type buried region 16 can be easily formed to a desired size. Consequently, because the N⁺-type buried region 16 can be prevented from being so formed as to extend to a position near the P⁻-type body region 12, it is possible to prevent the dielectric strength of the semiconductor device 1 from becoming low.

In the present embodiments, the P-type semiconductor substrate 2 and the P-type epitaxial layer 3 are so structured to have substantially the same impurity concentration, thereby the depletion layer 30 which is formed around the P⁻-type body region 12 when a voltage is applied to the P⁻-type body region 12 can be so formed as to extend by substantially a constant distance W into the P-type semiconductor substrate 2 and the P-type epitaxial layer 3. According to this structure, the distance L2 from the P⁻-type body region 12 to the N⁺-type buried region 16 is made substantially equal to the distance L1 from the P⁻-type body region 12 to the N⁺-type drain region 15, thereby the dielectric strength between the N⁺-type buried region 16 and the P⁻-type body region 12 and the dielectric strength between the N⁺-type drain region 15 and the P⁻-type body region 12 can be easily so made as to have the same largeness. In other words, it is possible to prevent the dielectric strength of the semiconductor device 1 (the LDMOS 10) from being limited by either one of the dielectric strengths, that is, the dielectric strength between the N⁺-type buried region 16 and the P⁻-type body region 12 or the dielectric strength between the N⁺-type drain region 15 and the P⁻-type body region 12.

In the present embodiments, the P-type epitaxial layer 3 is formed to a thickness of about 5 μm to about 7 μm (3 μm or more), thereby because the N⁺-type buried region 16 can be prevented from being so formed as to extend to a position near the P⁻-type body region 12, it is possible to prevent the dielectric strength of the semiconductor device 1 from becoming low.

In the present embodiments, the P-type epitaxial layer 3 is formed to a thickness of about 5 μm to about 7 μm (7 μm or less), thereby because it is not necessary to form the N⁺-type drain region 15 so deeply as to connect N⁺-type drain region 15 to the N⁺-type buried region 16, the impurity concentration of the connection portion between the N⁺-type drain region 15 and the N⁺-type buried region 16 can be prevented from becoming too low. Accordingly, the resistance between the N⁺-type buried region 16 and the N⁺-type drain region 15 can be prevented from becoming large.

In the present embodiment, the N⁺-type drain region 15 is formed at the same time as the N⁺-type collector compensation region 25 of the bipolar transistor 20, and the N⁺-type buried region 16 is formed at the same time as the N⁺-type collector buried region 26 of the bipolar transistor 20. Accordingly, productivity in producing the N⁺-type drain region 15 and the N⁺-type buried regions 16 can be increased compared with that in the case where the N⁺-type drain region 15 and the N⁺-type buried region 16 are produced in the processes different from those for the N⁺-type collector compensation region 25 and the N⁺-type collector buried region 26 of the bipolar transistor 20.

It must be considered that the embodiments disclosed this time are examples in all respects and are not limiting. The scope of the present invention is not given by the above explanations of the embodiments but by the claims, and all modifications within the scope of the claims and the meaning equivalent to the claims are included.

For example, in the present embodiments described above, the first electroconductive type is the P type, and the second electroconductive type is the N type. However, this is not limiting in the present invention, that is, the first electroconductive type may be the N type, and the second electroconductive type may be the P type. Also in this case, it is possible to obtain a semiconductor device which has a high dielectric strength and allows the on resistance to be made sufficiently small.

In the present embodiments described above, the example is explained, in which the N-type impurity concentration profile in the depth direction of the N⁺-type drain region and the N⁺-type buried region has the two impurity concentration peaks. However, this is not limiting in the present invention. As the modification shown in FIG. 5, it may be structured in such a manner that the N-type impurity concentration profile in the depth direction of the N⁺-type drain region and the N⁺-type buried region has three or more impurity concentration peaks. Specifically, energy of the ion implantation to form the N⁺-type drain region is made large, thereby the N⁺-type drain region is formed to a deeper position. In this way, the N⁺-type drain region is so formed as to have one impurity concentration peak in the surface portion and the other impurity concentration peak in the region other than the surface portion. Even if the energy of the ion implantation is made large, the impurity region is formed only to a depth of about 1 μm to about 2 μm at the most, it is hard to obtain a constant formation depth, and is impossible to make the impurity concentration large. Therefore, it is hard to form an impurity region (an N⁺-type buried region) by ion implantation in the position right under the N⁺-type drain region 15.

In the present embodiments described above, the example is explained, in which the distance from the P⁻-type body region to the N⁺-type buried region is made substantially equal to the distance from the P⁻-type body region to the N⁺-type drain region. However, this is not limiting in the present invention, that is, the distance from the P⁻-type body region to the N⁺-type buried region may be made different from the distance from the P⁻-type body region to the N⁺-type drain region.

In the present embodiments described above, the example is explained, in which the N⁺-type drain region is formed to substantially the same depth as that of the P⁻-type body region or to a depth deeper than the P⁻-type body region. However, this is not limiting in the present invention, that is, the N⁺-type drain region may be made to a depth smaller than that of the P⁻-type body region.

In the present embodiments described above, the example is explained, in which phosphorus (P) and antimony (Sb) are used to form the N⁺-type drain region and the N⁺-type buried region, respectively. However, this is not limiting in the present invention. In other words, arsenic (As) or other materials may be used to form the N⁺-type drain region and the N⁺-type buried region.

In the embodiments described above, the example is explained, in which the P-type epitaxial layer is formed to a thickness of about 5 μm to about 7 μm. However, this is not limiting in the present invention, that is, the P-type epitaxial layer may be formed to a depth smaller than 5 μm, or may be formed to a depth larger than 7 μm. In this case, it is desirable that the P-type epitaxial layer is formed to a thickness of about 3 μm or more to prevent the N⁺-type buried region from being formed near the P⁻-type body region so that the dielectric strength of the semiconductor device is prevented from becoming low.

In the embodiments described above, the example is explained, in which the connection portion between the N⁺-type drain region and the N⁺-type buried region is so structured as to have an impurity concentration of about 2×10¹⁸ atoms/cm³ or more. However, this is not limiting in the present invention. In other words, the connection portion between the N⁺-type drain region and the N⁺-type buried region may be so structured as to have an impurity concentration smaller than about 2×10¹⁸ atoms/cm³. In this case, it is desirable that the connection portion between the N⁺-type drain region and the N⁺-type buried region is so structured as to have an impurity concentration of about 1×10¹⁸ atoms/cm³ or more so that the resistance of the connection portion between the N⁺-type drain region and the N⁺-type buried region is made sufficiently small.

In the embodiments described above, the example is explained, in which the LDMOS and the bipolar transistor are disposed in the semiconductor device. However, this is not limiting in the present invention, that is, the bipolar transistor may not be disposed in the semiconductor device.

What is claimed is:

1. A semiconductor device comprising:
a first electroconducive-type semiconductor layer; and
a gate electrode which is disposed on a given region of an insulation film formed on the main surface of the semiconductor layer,
the semiconductor layer includes:
a second electroconducive-type drift region which is so formed as to cover a lower side of the gate electrode;
a body region of the first electroconducive type which is formed near the main surface side in the drift region;
a source region of the second electroconducive type which is formed near the main surface side in the body region and near one side of the gate electrode;
a drain region of the second electroconducive type which is formed near the main surface side in the drift region and near the other side of the gate electrode;
a buried region of the second electroconducive type which is formed in a position that is not right under the body region and right under at least the drain region and is connected to the drain region,
the semiconductor layer includes:
a semiconductor substrate of the first electroconducive type; and
an epitaxial layer of the first electroconducive type which is formed on the semiconductor substrate,
wherein the buried region is formed from an upper portion of the semiconductor substrate and to a lower portion of the epitaxial layer.

2. The semiconductor device according to claim 1, wherein
an end portion of the buried region near the body region side is formed closer to the body region side than an end potion of the drain region near the body region side.

3. The semiconductor device according to claim 1, wherein
an impurity concentration profile of the second electroconducive type in a depth direction of the drain region and the buried region has at least two impurity concentration peaks, that is, one impurity concentration peak in the drain region and the other impurity concentration peak in the buried region.

4. The semiconductor device according to claim 1, wherein
the distance from the body region to the buried region is substantially the same as that from the body region to the drain region.

5. The semiconductor device according to claim 1, wherein
the drain region is formed to substantially the same depth as that of the body region or to a depth larger than the body region.

6. The semiconductor device according to claim 1, wherein
the first electroconductive type is a P type, and the second electroconductive type is an N type.

7. The semiconductor device according to claim 6, wherein
an N-type impurity used to form the drain region is phosphorus.

8. The semiconductor device according to claim 6, wherein
an N-type impurity used to form the buried region is antimony or arsenic.

9. The semiconductor device according to claim 1, wherein
the epitaxial layer has a thickness smaller than the sum of a diffusion distance of impurity which is diffused from the main surface of the epitaxial layer in a depth direction to form the drain region, and a diffusion distance of impurity which is diffused toward the drain region side to form the buried region.

10. The semiconductor device according to claim 1, wherein
a connection portion between the drain region and the buried region has an impurity concentration which is 1×10¹⁸ atoms/cm³ or more and equal to or less than the maximum value of impurity concentrations of the drain region and the maximum value of impurity concentrations of the buried region.

11. The semiconductor device according to claim 10, wherein
the maximum value of impurity concentrations of the buried region is 1×10¹⁹ atoms/cm³ or more and 1×10²⁰ atoms/cm³ or less.

12. The semiconductor device according to claim 1, wherein
the semiconductor substrate and the epitaxial layer have substantially the same impurity concentration.

13. The semiconductor device according to claim 1, wherein
the epitaxial layer has a thickness which is 3 μm or more and 7 μm or less.

14. The semiconductor device according to claim 1, further comprising a collector compensation region and a collector buried region to form a bipolar transistor,
the drain region is formed at the same time as the collector compensation region of the bipolar transistor, and
the buried region is formed at the same time as the collector buried region of the bipolar transistor.
